(19) United States
(12) Patent Application Publication
(10) Pub. No.: US 2024/0279049 A1
(43) Pub. Date: Aug. 22, 2024

(54) INTERPOSER FOR DAMPING MEMS MICROPHONES

(71) Applicant: HAHN-SCHICKARD-GESELLSCHAFT FÜR ANGEWANDTE FORSCHUNG E. V., Villingen-Schwenningen (DE)

(72) Inventors: Achim BITTNER, Heilbronn (DE); Alfons DEHÉ, Reutlingen (DE)

(21) Appl. No.: 18/570,858

(22) PCT Filed: Jun. 17, 2022
(86) PCT No.: PCT/EP2022/066577

§ 371 Date: Dec. 15, 2023

(30) Foreign Application Priority Data
Jun. 18, 2021 (EP) 21180252.5

(51) Int. Cl. B81B 3/00; B81C 1/00

(52) U.S. Cl. CPC B81B 3/0051; B81C 1/00158; B81B 2201/0257; B81B 2203/0127; B81B 2203/0315; B81C 2203/035

(57) ABSTRACT

In a first aspect, the invention relates to a system comprising a MEMS microphone comprising a sound inlet opening, a vibratable microphone membrane and an electronic circuit, wherein when the microphone membrane is excited by sound waves entering through the sound inlet opening, an electrical signal that is dependent on the sound waves is generated by vibrations of the microphone membrane. A damping element for reducing the sound pressure level of the sound waves acting on the microphone membrane is mounted in front of the sound inlet opening, wherein the damping element comprises an elastic and vibratable damping membrane and wherein, in addition to the microphone membrane, the damping element is induced into vibrations by the sound waves such that the sound energy of the sound waves is divided between the damping membrane and the microphone membrane. This makes it possible in particular to extend the measuring range of the MEMS microphone without distortion to high sound pressure levels that could not previously be measured with the MEMS microphones known in the prior art.

In a further aspect, the invention relates to the use of the system according to the invention for aeroacoustic measurements, preferably for measuring sound pressure waves on surfaces of a vehicle component.

In a first aspect, the invention relates to a system comprising a MEMS microphone having a sound inlet opening, a vibratable microphone membrane and an electronic circuit, wherein, when the microphone membrane is excited by sound waves entering through the sound inlet opening, an electrical signal that is dependent on the sound waves is generated by vibrations of the microphone membrane. A damping element for reducing a sound pressure level of the sound waves acting on the microphone membrane is mounted in front of the sound inlet opening, wherein the damping element comprises an elastic and vibratable damping membrane and wherein the damping element, in addition to the microphone membrane, is preferably induced into vibrations by the sound waves such that the sound energy of the sound waves is divided between the damping membrane and the microphone membrane. This makes it possible in particular to extend the measuring range of the MEMS microphone to high sound pressure levels without distortion, which could not previously be measured with the MEMS microphones known in the prior art.

In a further aspect, the invention relates to the use of the system according to the invention for aeroacoustic measurements, preferably for measuring sound pressure waves on surfaces of a vehicle component.

### BACKGROUND AND PRIOR ART

Today, microsystems technology is used in many areas of application for the production of compact, electromechanical devices. The microelectromechanical systems (MEMS for short) that can be produced in this way are very compact (micrometer range) and at the same time offer outstanding functionality and ever lower production costs.

In particular, microphones based on MEMS technology, so-called MEMS microphones, are known in the prior art. A MEMS microphone comprises a vibratable microphone membrane that is configured to receive sound waves from a fluid. The fluid can be either a gaseous or a liquid fluid. The pressure waves are preferably sound pressure waves. A MEMS microphone preferably converts pressure waves into electrical signals.

MEMS microphones are characterized by their simple and compact design. This makes them particularly easy to arrange in arrays, which is important for sound measurements with a directional characteristic. In addition, they can be produced using widespread, extensively automated semiconductor technology processes.

The majority of MEMS microphones are designed for audio applications, i.e. for telephones and/or hearing aids. These applications are usually characterized by a bandwidth of less than 20 KHz and a sound pressure level of less than approx. 120 dB.

In the prior art, there are also approaches to designing MEMS microphones for aeroacoustic applications. Aeroacoustics deals with the generation and propagation of aerodynamically generated noise and its reduction. The importance of aeroacoustics has increased significantly in the aviation and automotive industries in recent years. In vehicle acoustics, this is due to the growing comfort awareness of customers.

However, MEMS microphones for audio applications are unsuitable for aeroacoustics, as aeroacoustics have different requirements in terms of sound variables.

The sound pressure level in the vicinity of a jet engine, for example, can be very high. Therefore, an aeroacoustic MEMS microphone should be capable of distortion-free operation up to 160 dB or more. The FAA (Federal Aviation Administration of the USA) requires a frequency range above 45 Hz<f≤11.2 kHz for the certification of commercial aircraft. However, aeroacoustic measurements of aircraft and their components are often performed on scale models, such that the frequency range of interest is scaled up accordingly. For example, the frequency range for a 1:8 scale model extends up to 89.6 kHz. Therefore, the bandwidth of an aeroacoustic MEMS microphone must be up to 90 KHz to be suitable for model testing (for this information, see David T. et al. (2007) I. Introduction).

In the prior art, there are various approaches for a MEMS microphone that can be used for aeroacoustic measurements.

Martin et al. (2007) suggest attaching two additional back plates between the microphone membrane. In the corresponding production process, a lower backplate is first coated onto a wafer. The lower backplate is located below the microphone membrane. Once the microphone membrane has been mounted, an upper backplate is applied above the microphone membrane. Both back plates have perforated holes. The sound passes through the holes onto the microphone membrane to cause it to deflect. They also have the function of reducing the damping in the spaces between the microphone membrane and the two back plates. Both the back plates and the microphone membrane are made of polysilicon. The MEMS microphone can measure sound pressure levels of up to 164 dB (with a reference of 20 μV/Pa). Measurement of higher sound pressure levels is not disclosed.

Sheplak et al. (1999) disclose a piezoresistive MEMS microphone comprising a thin microphone membrane that builds up a mechanical bending stress when subjected to sound pressure. The mechanical stress is measured by means of a change in electrical resistance of a structure made of piezoresistive material lying on the membrane. The piezoresistors are placed on the microphone membrane in a Wheatstone bridge configuration. The MEMS microphone can measure a sound pressure level of up to 155 dB.

Horowitz et al. (2007) disclose a piezoelectric MEMS microphone that is suitable for aeroacoustic measurements. Here, the mechanical voltage of a deflected membrane generates an electrical voltage when sound is excited at a sandwich structure consisting of two electrodes and a piezoelectric layer. However, the sensitivity achieved is relatively low and the microphone can measure a maximum sound pressure level of up to 169 dB.

DE 10 2019 124236 A1 discloses a sound measuring apparatus with an acoustic MEMS sensor mounted on a circuit board, wherein, in addition to a sensor membrane of the MEMS sensor that can be deflected by sound, behind a sound hole formed in the circuit board, a damping membrane spans the hole cross-section of the sound hole and is rigidly supported at the edge. By providing the damping membrane, the sound level of the sound passing through the sound hole is to be reduced in order to enable measurement methods with high maximum sound levels. A linear reduction of the sound pressure level should be achieved with a suitable elastic design of the damping membrane. Specific values regarding the reduction of the sound pressure level are not disclosed.

Other MEMS microphones are also known in the prior art having an additional membrane which however is not designed to reduce sound pressure levels.

For example, US 2019/335262 A1 discloses a microphone arrangement comprising a MEMS transducer, wherein the MEMS transducer has an elastomeric membrane. The elastomeric membrane serves to protect against contamination and is said to have a negligible influence on the acoustic performance. In particular, the elastomeric membrane should be acoustically transparent and lead to a reduction of the SNR (signal-to-noise ratio) of less than 1%.

US 2020/107096 A1 discloses a microphone arrangement comprising a port membrane for protection against the ingress of liquids. In particular, the port membrane should be gas-permeable in order to be permeable or transparent for acoustic energy. Furthermore, the acoustic energy should be able to be transmitted with little or no damping. In particular, at most losses of sound power of about 3.5 dB should be acceptable in the context of the disclosure of US 2020/107096 A1. In addition to the port membrane, the microphone arrangement may comprise an acoustic mesh, which is described as a wire mesh. The wire mesh can either be acoustically transparent or achieve a frequency-dependent damping, whereby the acoustic signal can be distorted.

MEMS microphones that can measure sound pressure levels of up to 180 dB are also required for certain aeroacoustic measurements. The MEMS microphones known from the prior art are not designed for such high sound pressure levels.

Microphones that can measure such high sound pressure levels have a larger design. However, larger designs have the disadvantage that they influence the air flow itself due to their dimensions. However, in order to ensure accurate measurements, it is important to avoid influencing the flow through the microphone itself. In particular, it is no longer possible to measure small lateral resolutions of the flow behavior if the microphone is too large. In addition, large microphones are not suitable for mounting on technical surfaces such as aircraft surfaces or automotive components.

In addition, microphones that can measure such high sound pressure levels, as are important in aeroacoustics, are only available at very high cost.

MEMS microphones that can measure very high sound pressure levels, particularly suitable for aeroacoustics, with high lateral resolution of the smallest turbulence in the air flow and are also inexpensive to produce are not known from the prior art.

### Objective of the Invention

The objective of the present invention was to eliminate the disadvantages of the prior art and to provide an improved system which can measure very high sound pressure levels, whereby the measurement results are high-resolution and there is no distortion of the measurement results. In particular, one objective was to provide systems that are suitable for aeroacoustic measurements. In addition, the systems should be easy and inexpensive to produce.

### SUMMARY OF THE INVENTION

The objective according to the invention is solved by the features of the independent claims. Advantageous embodiments of the invention are described in the dependent claims.

In a preferred embodiment, the invention relates to a system comprising
a) a MEMS microphone comprising a sound inlet opening, a vibratable microphone membrane and an electronic circuit, wherein, when the microphone membrane is induced into vibrations by sound waves entering through the sound inlet opening, an electrical signal dependent on the sound waves is generated, and
b) a damping element for reducing the sound pressure level of the sound waves acting on the microphone membrane
   characterized in that the damping element comprises an elastic and vibratable damping membrane, which is mounted in front of the sound inlet opening. Preferably, in addition to the microphone membrane, the damping membrane is induced into vibrations by the sound waves, such that sound energy from the sound waves is preferably divided between the damping membrane and the microphone membrane.

The system according to the invention has proven to be advantageous in many aspects, which will be explained in more detail below.

Advantageously, the system according to the invention is capable of measuring particularly high sound pressure levels. In particular, the system can measure sound pressure levels of up to 200 dB, which is not possible with the MEMS microphones known in the prior art.

The technical reason for this is that the sound energy is divided between the microphone membrane and the damping element, which comprises an elastic and vibratable damping membrane. Sound waves are accompanied by alternating movements of particles in the medium in which the sound propagates. At the same time, parts of the medium are alternately compressed and attenuated. The energy that the sound possesses can therefore be represented as the sum of kinetic and potential energy. When the sound enters, it first hits the damping element, which comprises an elastic and vibratable damping membrane, and transfers part of its energy to it. In the context of the invention, this energy transfer can be described as a first energy transfer. After the first energy transfer by the sound, the sound passes through the sound inlet opening onto the microphone membrane, causing the microphone membrane to vibrate. The energy transfer of the sound to the microphone membrane of the MEMS microphone can be understood as a second energy transfer in the context of the invention.

The vibrations of the microphone membrane preferably represent the actual measured signal, which is generated by the transmission of the vibrations to an electrical circuit that is connected to the MEMS microphone.

In particular, the distribution of sound energy to the damping element and the microphone membrane is largely loss-free and distortion-free. This is due to the elasticity of the damping membrane. The elasticity of the damping membrane refers to the property that it changes its shape when force is applied and returns to its original shape when the applied force is removed, similar to a spring. In fact, the vibration of the damping membrane is caused by the fact that it is elastic and a sound wave is a spatial propagation of a mechanical vibration caused by vibrations of a fluid, in particular air, in space. As the vibration propagates, energy is transferred, first to the damping membrane and then to the microphone membrane. The damping membrane is elastic and in particular non-plastic, i.e. it changes its shape under the effect of a sound wave and returns to its original state.

Preferably, the damping element and the microphone membrane have the same vibration behavior, but the vibrations of the damping element have a lower amplitude than those of the microphone membrane. It is noteworthy in this context that the full bandwidth of the measured sound is retained and, in particular, no part of the bandwidth is lost. The vibration behavior of the microphone membrane is not qualitatively changed by the provision of the elastic damping membrane. Instead, the amplitude of the vibrataing microphone membrane is reduced without distortion across the entire frequency spectrum by dividing the sound energy. Frequency-dependent damping, which is more pronounced at higher frequencies than at lower frequencies, for example, is avoided. In addition, the signal-to-noise ratio (SNR ratio) of a measured acoustic signal is maintained by dividing the sound energy of the incident sound between the damping element and the microphone membrane.

The mode of operation of the system according to the invention can be explained to a certain extent by analogy with a level shifter from electrical engineering.

In electrical engineering, a level shifter is a discrete or integrated electronic circuit that adapts the signal levels—usually voltage levels—of one component to another component, a transmitter and a receiver. As not all components work with the same voltage levels, it is necessary to adapt (adjust) the signal levels of the information signals in order for these components to communicate with each other. Depending on the requirements, this adaptation can be carried out using an active or passive electronic circuit. In analog circuits, signal levels of the transmitter are usually adapted to those of the receiver by means of amplifiers. For example, the signal of a microphone is adapted to the input signal level range of the AUX input of an amplifier by a microphone preamplifier.

However, there are applications where a simple amplification or attenuation of the information signal is not sufficient and the signal must also be shifted in the voltage range. For example, if an audio signal with a typical voltage range of −100 mV to 100 mV is to be digitized, it is not only necessary to amplify this signal, but also to shift it by adding an offset voltage, for which a subtractor amplifier circuit is suitable.

By analogy, the inventors recognized that the microphone membrane of a MEMS microphone is not suitable for detecting the high sound pressure levels that occur particularly in aeroacoustics. By mounting the damping element as an elastic vibratable membrane, the high sound pressure level can be advantageously shifted so that the microphone membrane can measure the shifted range. This is achieved by absorbing a portion of the high sound pressure level in order that a further portion of the sound pressure level is detectable by the microphone membrane. The signal is not distorted, for example by frequency-dependent damping.

A further physical analog for illustrating the idea according to the invention can be seen in the mechanical principle of action of a series connection of two springs. In the case of springs connected in series, an acting force is not divided (as in the parallel connection), but acts with the same value through the two springs. The springs can have different spring constants and different lengths when connected in series, which has a corresponding effect on the overall change in length. The damping element and the microphone membrane are also coupled, such that when a force is applied to the damping element by incoming sound waves, the microphone membrane is also induced into vibrations by undistorted sound waves propagating after the damping element.

The system according to the invention can be advantageously used as an instrument in particular to carry out high-resolution measurements of sound variables, such as high sound pressure levels, for example in a wind tunnel. It is also possible for the system according to the invention to be installed on surfaces where high values of sound pressure levels occur, for example on the surface of components of an aircraft. It is also possible to use the system according to the invention to measure the propagation of sound waves on other surfaces or vehicles. An average person skilled in the art is able to use the system according to the invention in various fields.

Another advantage of the system according to the invention is that it has very small dimensions. In particular, the lateral extension of the system according to the invention can be kept to a minimum. This is advantageous in that the system according to the invention does not influence the air flowing around it. As a result, measurement results are not distorted and are reproduced particularly accurately. In particular, the slightest turbulence in the air flowing around it can be detected in order to determine the exact flow behavior of the fluid flowing around it, in particular air, and/or very detailed sound variables. In particular, it is advantageously possible to determine very low lateral resolutions of the sound pressure level.

The miniaturization of the system according to the invention is accompanied by further advantages. The small dimensions of the system according to the invention result in a higher density of systems, which can be formed along an array, for example. By using a high number of systems according to the invention or of MEMS microphones, measurement results can be determined particularly precisely. In addition, due to the high number, the measurement quality does not suffer if individual systems of an array should fail for any reason.

By arranging the system according to the invention in an array, applications are also possible that use beamforming, for example, to determine measurement values specifically from a certain direction. In this way, for example, a sound pressure level can be directed from a desired position and determined with a high degree of accuracy. Various forms of arrays are known from the prior art, for example one-dimensional, two-dimensional and/or three-dimensional arrays.

It is a further advantage that the damping element can be installed together with a MEMS microphone in accordance with the invention, since MEMS microphones are available in very small housings that are suitable for SMT (surface-mounting technology) assembly, among other things, without restriction. MEMS microphones also have excellent temperature properties. The temperature resistance of the system can be particularly desirable for aeroacoustic applications.

Preferably, by providing the damping membrane, the system can form a closed system, so that when the system according to the invention is mounted on a surface, the ingress of undesirable matter, e.g. dirt, soot and/or dust, into the system is prevented. In particular, internal components of the system according to the invention, for example internal components of the MEMS microphone, are not damaged. Thus, the damping element not only has the function of shifting the sound pressure level to a range that can be measured by the microphone membrane without distortion, but also represents a protective and barrier function with respect to the environment. Furthermore, it is possible to prevent the adhesion of dirt via an anti-adhesive coating or to remove dirt adhering to the surface of the system particularly easily.

Furthermore, the system according to the invention is preferably also suitable for installation on flexible surfaces, for example in which flexible printed circuit boards are used to position the damping element and the MEMS microphone. This means that the system according to the invention is not limited to fixed shapes or structures of surfaces and advantageously has a wide range of applications. It is thus possible to attach the system to corners, edges, curves and/or curved and/or bent surfaces.

In addition, the system according to the invention can be produced using standardized semiconductor and microsystem technology processes, so that proven, automated methods of semiconductor processing can be used and cost-effective mass production can be implemented. A MEMS microphone preferably refers to a microphone that is based on MEMS technology and whose sound-receiving structures are at least partially dimensioned in the micrometer range (approx. 1 μm to approx. 1000 μm). The sound-receiving structures are referred to as the microphone membrane. Preferably, the microphone membrane can have a dimension in the range of less than 1000 μm in width, height and/or thickness. In particular, the microphone membrane is vibratable.

The microphone membrane is configured to receive sound waves from the fluid. The fluid can be either a gaseous or liquid fluid. The pressure waves are preferably sound pressure waves. A MEMS microphone therefore preferably converts pressure waves into electrical signals. An electronic circuit can preferably be used to read out the vibratable membrane, the vibrations of which are generated by piezoelectric, piezoresistive or capacitive components on the membrane, for example. The microphone membrane is preferably sufficiently thin so that it bends under the influence of the changes in air pressure caused by the sound waves and transitions into a vibrating behavior. As the microphone membrane vibrates, electrical variables can change, such as the capacitance between the membrane and the rear wall. The change in an electrical variable, such as a change in capacitance, can be converted into an electrical signal by an electrical circuit built into the MEMS microphone, such as an ASIC or a computing unit. The electrical circuit measures changes in such electrical variables, for example voltage changes, current changes or capacitance changes, which occur when the microphone membrane vibrates under the influence of sound waves.

The sound inlet opening preferably refers to an opening in the MEMS microphone through which sound waves can pass and come into contact with the microphone membrane. Preferably, the sound inlet opening is located in front of the microphone membrane in the direction of flow of the fluid, in particular air.

The electronic circuit preferably converts the vibrations of the microphone membrane into electrical signals. This is based on the fact that one or more electrical variables, such as a voltage and/or a capacitance, change when the microphone membrane vibrates. The electronic circuit preferably comprises electrical connections, for example wires, which are in contact with the microphone membrane. In addition, the electronic circuit can have an ASIC (application-specific integrated circuit), a computing unit, an integrated circuit (IC), a programmable logic device (PLD), a field programmable gate array (FPGA), a microprocessor, a microcomputer, a programmable logic controller and/or other electronic circuit elements. The vibrations of the microphone membrane cause the electronic circuit to generate an electrical signal that is dependent on the sound waves and therefore also on the amplitudes of the vibrations of the microphone membrane.

Sound preferably refers to a mechanical deformation in a medium that progresses as a wave. In a fluid, sound is always a longitudinal wave, especially in air. The terms “sound” and “sound wave” can therefore be used synonymously. In gases such as air, sound can be described as a sound pressure wave superimposed on the static air pressure. In the case of sound waves, the fluctuations of the state variables of pressure and density are usually small in relation to their control variables. If air is discussed below as a fluid of sound waves, the average person skilled in the art knows that the explanations can also be applied to other fluids.

The damping element preferably refers to a component of the system according to the invention, which preferably serves to reduce the sound pressure level of the sound waves acting on the microphone membrane. Since the microphone membrane cannot measure sound pressure levels that are too high, the damping element shifts the sound pressure level of the sound wave without distortion in a range that can be measured by the microphone membrane. In particular, undistorted shifting means that no information and/or values of the actual sound pressure level are lost. Preferably, the bandwidth of the measured signal is retained and the signal-to-noise ratio remains unchanged. For this purpose, the sound energy of the sound wave is divided between the microphone membrane and the damping element without distortion as described above. For this purpose, the damping element comprises in particular an elastic, vibratable damping membrane. This preferably vibrates with the same qualitative vibration behavior as the microphone membrane when a sound wave hits the system.

Mounting the damping element in front of the sound inlet opening preferably refers to a design of the system according to the invention in which a sound wave first hits the damping element before it reaches the microphone membrane. Therefore, from the point of view of an incident sound wave, the damping element is preferably the first component of the system according to the invention. In particular, the sound wave first causes the damping element to vibrate before causing the microphone membrane to vibrate. The vibrations of the damping element and the microphone membrane can therefore be out of phase. Although the vibration behavior of the damping element and the damping membrane are essentially the same, they differ in amplitude and phase.

Terms such as substantially, approx. etc. preferably describe a tolerance range of less than ±40%, preferably less than ±20%, particularly preferably less than ±10%, even more preferably less than ±5% and in particular less than ±1% and in particular comprise the exact value. Similar preferably describes quantities that are approximately equal. Partial preferably describes at least 5%, particularly preferably at least 10%, and especially at least 20%, in some cases at least 40%.

In a further preferred embodiment, the system according to the invention is characterized in that dividing the sound energy of the incident sound waves between the damping membrane and the microphone membrane leads to a reduction in the sound pressure level acting on the microphone membrane by at least 10 dB, preferably by at least 20 dB, particularly preferably by at least 30 dB.

Advantageously, by reducing the sound pressure level acting on the microphone membrane by the values mentioned, it is possible to measure particularly high sound pressure levels, such as those found in aeroacoustics in particular, for example approx. 175 dB, without distortion. This extends the range of application of the system according to the invention. In contrast, the MEMS microphones known in the prior art are not capable of measuring such high sound pressure levels, e.g. up to 170 dB, 175 dB, 180 dB, 185 dB, 190 dB, 195 dB, 200 dB or higher.

Such a reduction is not made possible by the membranes disclosed in US 2019/335262 A1 and US 2020/107096 A1, for example, and is also not desired in the context of these publications. The membranes of US 2019/335262 A1 and US 2020/107096 A1 rather serve to protect against contaminations, whereby a reduction of the sound power is to be avoided precisely by designing the membrane as acoustically transparent. The general possibility of reducing the sound pressure level is taught in DE 10 2019 124236 A1. However, neither the above-mentioned particularly preferred values nor the associated advantages are disclosed.

It is also a particular advantage that the system according to the invention can measure the lowest lateral resolutions of the sound pressure level. The lateral resolution here preferably refers to a resolution transverse to the course of a measurement path by means of sound waves. The opposite of lateral resolution is axial resolution along the longitudinal course of the measurement path, i.e. the path of the sound. In particular, the lateral resolution is the distance between two adjacent objects, e.g. two sound sources, which can be mapped as two points. This makes it possible to create a very accurate image of the sound field, despite high sound pressure levels.

A sound field preferably refers to the area in an elastic medium, especially in air, in which sound waves propagate. The sound pressure level (SPL) is the decadic logarithm of the quadratic relationship between the effective value of the measured sound pressure and its reference value of 20 μPa, which is commonly used in acoustics. The sound energy preferably refers to the energy contained in a sound field or a sound event, which, as already mentioned above, can be represented as the sum of kinetic and potential energy. The associated logarithmic variable is the sound energy level. According to the invention, the damping element is preferably an elastic body which is excited to mechanical vibrations by the effect of impinging sound waves. As a mechanical wave, sound does not transmit matter, but it does transmit energy. The sound energy of the sound wave is transmitted and divided into vibration energies of the damping element and the microphone membrane.

In particular, the kinetic energy term of the energy balance contains the sound pressure. Sound pressure refers to the pressure fluctuations of the medium, especially air, which occur during the propagation of sound. It is commonly expressed as an effective value, as it is a harmonic phenomenon in particular. The measured effective value of the sound pressure is included in the sound pressure level given in dB (decibels). This means that the sound pressure level is also reduced by dividing the sound energy between the damping element or damping membrane and the microphone membrane, such that very high sound pressure levels can be measured. In particular, the sound pressure level is not distorted and the signal-to-noise ratio remains unchanged.

In a further preferred embodiment, the system according to the invention is characterized in that the MEMS microphone has a housing in which the sound inlet opening is located.

The housing of the MEMS microphone preferably comprises a solid and in particular protective casing of the MEMS microphone. In particular, the housing advantageously serves to protect the components of the MEMS microphone, for example from foreign material and/or damage. However, the housing can also have other functions. For example, in addition to the protective function, the housing can also have a carrier function. Advantageously, dispensing with an additional supporting structure reduces the weight, the number of components, the assembly effort and thus also the production costs.

There are preferably attachment areas on the housing to connect the MEMS microphone to the housing. Conventional methods known in the prior art can be used, such as soldering and/or gluing. Such attachment options and methods are within the knowledge of the average person skilled in the art and will not be discussed in detail.

Preferably, the sound inlet opening is located on the housing above the microphone membrane. It may also be preferred for the sound inlet opening not to be located directly above the microphone membrane. The sound passes through the sound inlet opening to the microphone membrane, which is induced into vibrations by the sound waves. In addition, the electronic circuit generates a signal that indicates various sound variables, such as sound deflection, sound pressure, sound pressure level, sound energy density, sound energy, sound flow, sound velocity, sound impedance, sound intensity, sound power, sound velocity, sound amplitude and/or sound radiation pressure.

In a further preferred embodiment, the system according to the invention is characterized in that the damping membrane is formed from an elastic material, preferably selected from a group comprising monocrystalline silicon, polysilicon, silicon dioxide, silicon nitride, silicon carbide, silicon germanium, silicon nitride, nitride, germanium, carbon, gallium arsenide, gallium nitride, indium phosphide, glass and/or a metal. Preferably, these materials are as ideally elastic as possible, in which no plastic deformations occur when functioning as a damping membrane. In further preferred embodiments, the damping membrane may comprise a material comprising a fiber-plastic composite.

In a further preferred embodiment, the system according to the invention is characterized in that the damping membrane has a thickness of 50 nm to 500 μm, preferably 100 nm to 200 μm, particularly preferably 1 μm to 50 μm

The aforementioned materials and dimensions have proven to be particularly advantageous for providing a vibratable damping membrane. This is due to the fact that the materials mentioned, in particular with the thicknesses mentioned, have shown suitable elasticity for the system according to the invention. The damping membrane vibrates when sound waves are incident on it. In particular, the materials mentioned deform elastically and not plastically under the effect of sound waves. The damping membrane is therefore deformed reversibly in particular. If a sound wave acts on the damping membrane, the equilibrium position is disturbed and the damping membrane is deformed. As the sound wave is a propagation of vibrations, these are transmitted to the damping membrane and thus also set into vibration.

The vibration behavior of the damping membrane preferably corresponds substantially to the vibration behavior of the microphone membrane. There is a difference with regard to the vibration behavior in terms of amplitude and phase; the shape or form of the vibration is preferably substantially the same. Advantageously, the sound pressure level is thus shifted to measurable values so that even particularly high sound pressure levels can be detected by the system according to the invention. It is particularly advantageous that no values in the bandwidth of the measured sound event are lost. In addition, the signal-to-noise ratio remains the same. The measurement signal is advantageously shifted without distortion in such a way that high sound pressure levels, such as 175 dB, can be measured without distortion.

Furthermore, the use of the aforementioned materials as damping membranes is particularly advantageous in that they can be processed very easily using known and proven prior art methods. In addition to the aforementioned suitable elasticity, the materials mentioned are also robust and stable such that they do not tear despite the high sound pressure levels. They are also advantageously inexpensive to procure and process.

Furthermore, the aforementioned materials and values are advantageous for the manufacturing process of the system according to the invention, as they are suitable for mass production. In particular, standardized production techniques can be used for coating and/or machining to form the damping membrane.

In a further preferred embodiment, the system according to the invention is characterized in that the damping membrane extends at least over the sound inlet opening and/or the damping membrane has a lateral extension of 100 μm to 2000 μm, preferably 200 μm to 1000 μm.

The damping membrane thus covers at least the sound inlet opening, but can also extend beyond the sound inlet opening or over an entire surface above the sound inlet opening.

Extending the damping membrane over the sound inlet opening of the MEMS microphone provides the advantages described above with regard to shifting high sound pressure levels to a measurable area of the microphone membrane. Furthermore, the damping membrane provides additional protection for the MEMS microphone and its components, such as the electronic circuit and/or the microphone membrane.

Preferably, a closed system is formed by attaching the damping membrane and extending it over the sound inlet opening. This preferably hermetically seals the internal components of the MEMS microphone. A hermetic seal preferably means an absolutely tight seal, in particular one that prevents the exchange of air and/or water. This advantageously protects components of the MEMS microphone and increases its service life.

Preferably, the lateral extension of the damping membrane is matched to the lateral extension of the sound inlet opening.

Lateral extension here preferably refers to the lateral extension of the damping membrane, in particular extending outwards and/or along a surface. The lateral extension preferably refers to the maximum lateral extension of the damping membrane in its plane. In the case of the shape of a circle, lateral extension is therefore given by a diameter.

In a preferred embodiment, the lateral extension of the damping membrane may substantially correspond to the lateral extension of the sound inlet opening of the MEMS microphone. Thus, it may be preferred that the damping membrane extends at least over the sound inlet opening such that it is completely covered by the damping membrane. However, it may also be preferable for the damping membrane to be slightly smaller than the sound inlet opening, such that a smaller vibratable area is located in front of the sound inlet opening.

In the case of a sound inlet opening with a diameter of, for example, approx. 500 μm, the damping membrane can preferably have a diameter of at least approx. 500 μm, for example a diameter of approx. 600 μm, approx. 700 μm, approx. 800 μm, approx. 900 μm, approx. 1000 μm or more. However, it may also be preferred that the damping membrane has a smaller diameter than the sound inlet opening, in relation to the above example, for example a diameter of approx. 400 μm, approx. 300 μm, approx. 200 μm or less.

Preferably, the ratio of the lateral extension of the damping membrane to the lateral extension of the sound inlet opening can be more than 0.5, 0.6, 0.7, 0.8, 0.9, 1.0, 1.1, 1.2, 1.3, 1.4, 1.5, 2, 3 or more and/or less than 10, 9, 8, 7, 6, 5, 4, 3 or less. A person skilled in the art will recognize that intermediate ranges of the aforementioned parameters may be preferred, for example between 0.8 and 3, between 1.1 and 2 or even between 1.5 and 5.

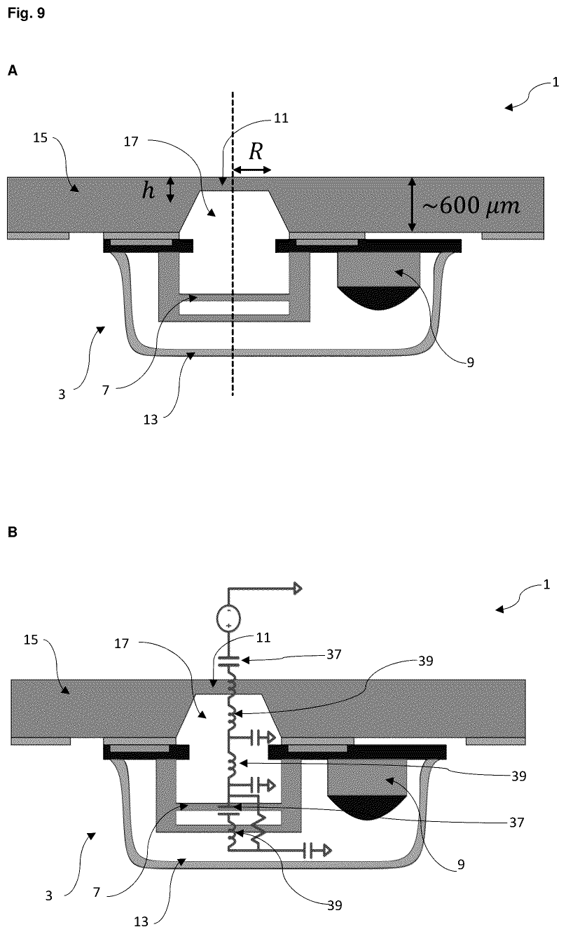

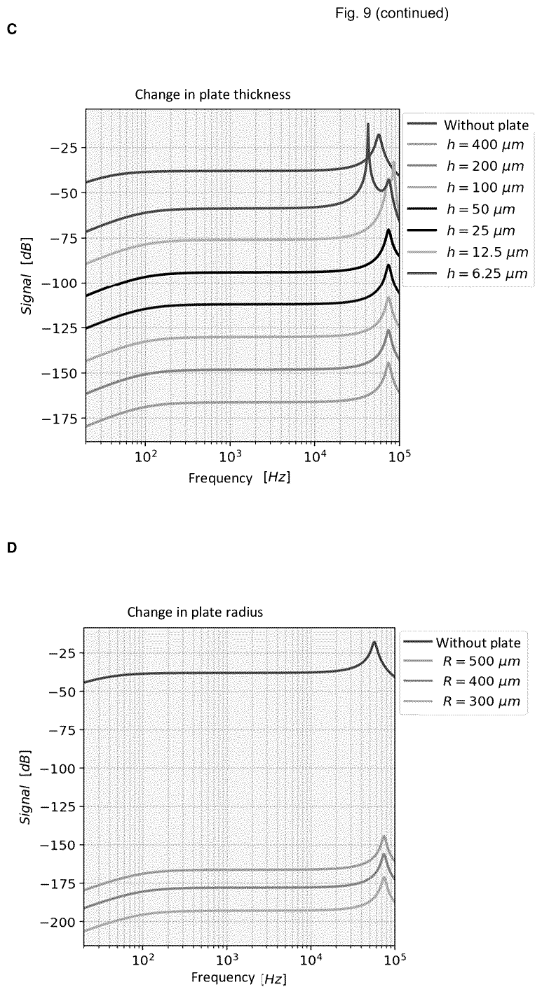

The lateral extension—for example a diameter or radius—of the damping membrane is another parameter that influences the effect of the damping membrane. FIG. 9E shows the dependence of the reduction in sound pressure level on the radius of the damping membrane. A smaller radius and thus a smaller lateral extension of the damping membrane leads to greater damping and increases the possible measurable range of the sound pressure level. On the other hand, with an at least substantially equally large

In a further preferred embodiment, the system according to the invention is characterized in that the MEMS microphone is a capacitive, piezoelectric and/or piezoresistive MEMS microphone and/or an electret microphone.

In a piezoelectric microphone, the microphone membrane is mechanically coupled to a piezoelectric element, which is minimally deformed by the pressure fluctuations. The piezoelectric effect results in voltage fluctuations due to the deformation of the piezoelectric element. These voltage fluctuations are transmitted to the electronic circuit and read out. Piezoelectric microphones are advantageously mechanically robust and have a simple design. They are particularly advantageous as they do not require an external power supply. They are also insensitive to high temperatures.

A piezoresistive microphone measures the mechanical voltage based on a change in the electrical resistance of a structure made of piezoresistive material on the microphone membrane. The piezoresistors can be connected in a Wheatstone bridge circuit on the microphone membrane. Due to the simple design, piezoresistive microphones can be integrated monolithically.

In a capacitive microphone, the microphone membrane is electrically insulated from an electrode layer, for example made of a metal or a semiconductor, which can in particular form a rear wall. From a technical point of view, this arrangement is analogous to a plate capacitor with an air dielectric that has an electrical capacitance. This depends on the plate area and the distance between the capacitor plates. The incidence of sound causes the microphone membrane to vibrate, which changes the distance between the membrane and the counter electrode and thus also the capacitance of the capacitor, which can be detected by the electronic circuit. Capacitive microphones are known in the prior art for their basic design and production. They are advantageously highly sensitive and are also insensitive to temperature.

Electret microphones are also based on a capacitive measuring principle and have an electret. Just as a permanent magnet carries a frozen magnetic field, an electret carries a frozen electric field. This takes over the bias voltage otherwise required for condenser microphones and thus allows simpler operation. Due to the high impedance, an impedance converter is necessary in most cases.

There are three types of electret microphones. In the membrane type, the membrane itself is the electret. In the front electret type, the electret is mounted on the membrane. In the back electret type, the electret is mounted on the fixed electrode layer, for example a metal layer or a small metal plate. Advantageously, electret microphones have a very compact design and low production costs with good signal quality.

In a further preferred embodiment, the system according to the invention is characterized in that the MEMS microphone is present in a top-port or bottom-port design and/or is integrated within a multilayer substrate, preferably a wafer stack.

In the course of the development of MEMS microphones, different housing types have become established. These can be categorized according to the way in which sound is delivered. If the sound reaches the microphone membrane via the underside of the housing, this is referred to as a bottom-port MEMS microphone. Bottom-port microphones also require an opening on the substrate on which the components of the MEMS microphone are located (also known as the carrier substrate), as this is the only path for sound waves to reach the microphone membrane. If the sound reaches the sensor via the top of the housing, it is referred to as a top-port MEMS microphone.

Whether a top-port or bottom-port microphone is preferred usually depends on factors such as the arrangement of the microphone in the product and/or manufacturing aspects.

Advantageously, the damping membrane according to the invention can be provided in a MEMS microphone in a top-port or bottom-port design. In addition, a MEMS microphone and a damping element can also be provided within a multilayer substrate, preferably a semiconductor substrate, which is also referred to as a wafer stack.

In a preferred embodiment, the MEMS microphone is present in the bottom port version, which can also be referred to as a bottom port microphone.

Bottom port designs have a large volume of air in the rear volume of the MEMS microphone, which makes it easier for the microphone membrane to move under the influence of the sound waves. This in turn improves the sensitivity and signal-to-noise ratio of the microphone. A large rear volume is also advantageous for the response of the system according to the invention to low frequencies.

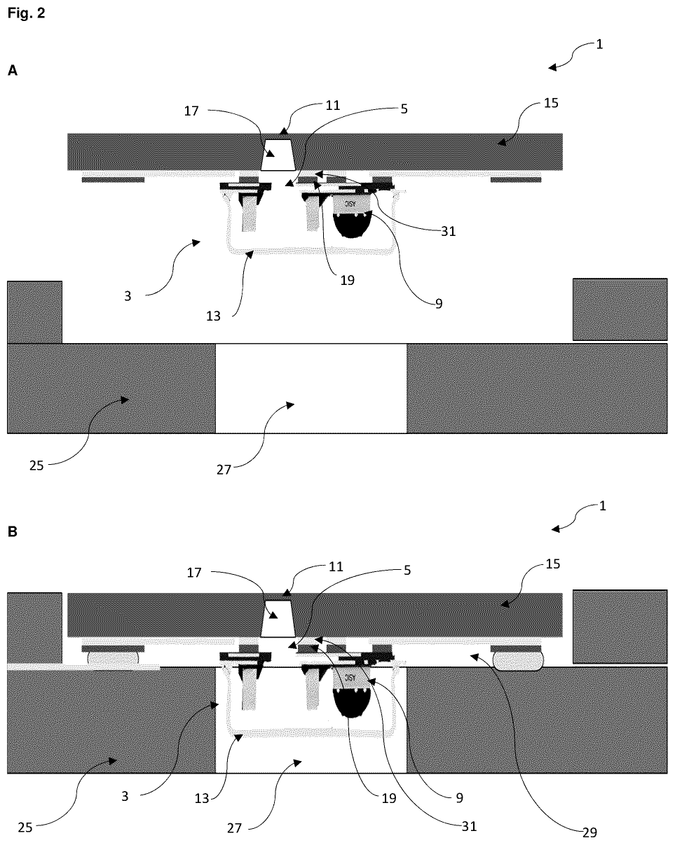

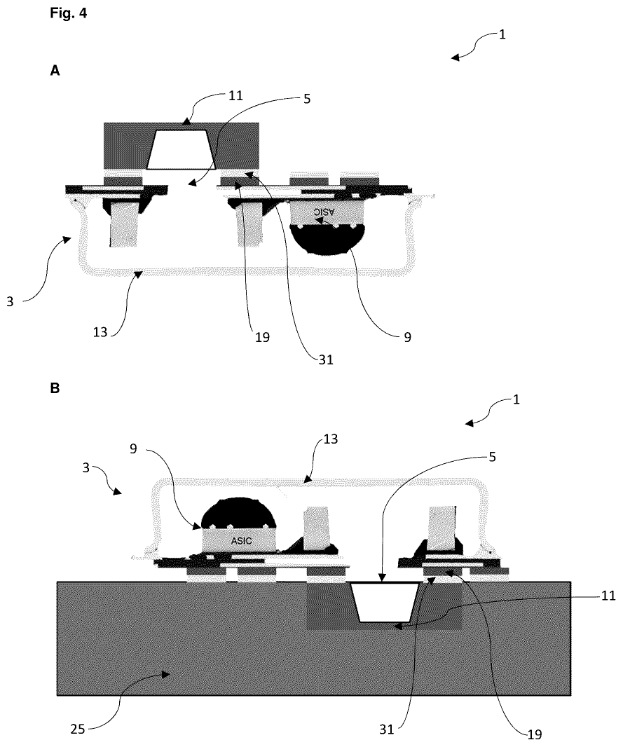

The damping membrane can preferably be placed in front of the sound inlet opening in such a way that the housing fits inside a cavity of a printed circuit board and the damping membrane extends along the sound inlet opening. In the case of bottom-port microphones, the damping membrane is therefore preferably located on the carrier substrate (see e.g. FIG. 2A-B). It may also be preferable for the damping membrane in the bottom port design to be located within a cavity of a printed circuit board (see FIG. 4B).

It is particularly preferred that the damping membrane in bottom port versions is provided by an interposer. The combination of the damping membrane with bottom-port microphones is very advantageous, as an interposer can be processed particularly easily to ensure the provision of a damping membrane and its connection to the MEMS microphone. In addition, the use of an interposer makes it advantageously possible to provide a damping membrane, electrical contacting and an acoustic seal at the same time.

In the bottom port design in particular, different assembly methods can also be distinguished. Known assembly methods are flip-chip assembly and wire-bond assembly, which can also be provided for the system according to the invention.

In flip-chip assembly, the connection between the microphone membrane, electronic circuit and carrier substrate is made using a solder. For this purpose, the microphone membrane, the electronic circuit and the solder are applied to the carrier substrate and mechanically and electrically connected to each other using a reflow process.

In the reflow process, a soft solder in the form of solder paste is preferably applied to the PCB before assembly. This is the main difference to other soldering processes such as soldering iron soldering, dip soldering or wave soldering. There are various ways of applying solder, e.g. using stencil printing (stencil, screen printing), dispensers, solder preforms or electroplating. The components are then assembled. The advantage of using solder paste is that it is sticky and the components adhere directly to the paste during assembly. They therefore do not have to be glued on separately. The assembled carrier substrate (e.g. a printed circuit board) is heated strongly enough to melt the solder contained in the solder paste. At the same time, the increased temperature activates the flux in the solder paste gel. The heating processes used for this purpose aim to heat the circuit board and the components as evenly as possible. The surface tension of the molten solder draws the components to the center of the landing pads.

One advantage of flip-chip mounting is the small and compact component size. With flip-chip mounting, additional bonding wires are not required as the electrical and mechanical connection is made directly to the carrier substrate. The mechanical connection to the carrier substrate influences the temperature response of the microphone. The different linear expansion coefficients of the materials of the components, such as silicon, carrier substrate, solder and adhesive, influence the mechanical tension of the microphone membrane. This leads to a change in the deflection and thus to a change in sensitivity.

In wire bonding, the connection between the microphone membrane, electronic circuit and carrier substrate is preferably made using bonding wires. For this purpose, the microphone membrane and the electronic circuit are first mechanically connected to the carrier substrate using adhesive, for example, and then electrically connected via bonding wires. MEMS microphones with a wire-bond assembly design advantageously have a large rear volume. Acoustic separation or separation of areas of the MEMS microphone is achieved by dividing the front and rear volumes. The front volume preferably comprises the volume from the sound inlet opening to the microphone membrane and the rear volume comprises the volume behind the microphone membrane.

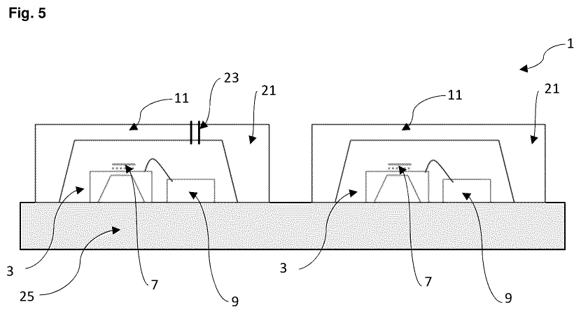

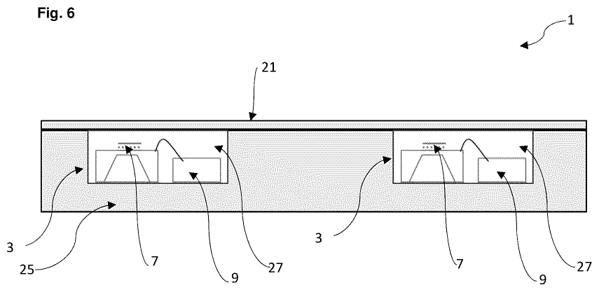

In top port versions of a MEMS microphone, the damping membrane is preferably planar in front of or above the sound inlet opening. For example, the damping membrane can be provided by the housing itself or an additional microphone cover (see e.g. FIG. 5-6).

In a further preferred embodiment, the system according to the invention is characterized in that the system comprises an interposer and the damping membrane is incorporated in the interposer. The installation of an interposer is particularly preferred in a bottom port version of a MEMS microphone.

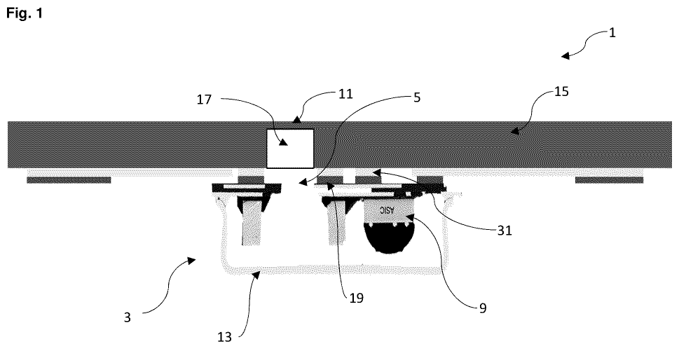

For example, the damping membrane can be provided in an interposer by inserting a cavity into the interposer. The cavity has a boundary layer that separates the cavity from the surroundings of the interposer. This boundary layer serves as a damping membrane, which is preferably located in front of the sound inlet opening (see also FIG. 1). As discussed above, a MEMS microphone in the bottom-port version can also be provided with the housing in a cavity of a circuit carrier, wherein the interposer with the inserted cavity is located in front of the sound inlet opening (see FIG. 2B).

The presence of the damping membrane in the interposer has proven to be particularly advantageous. In particular, a damping membrane, electrical contacting and an acoustic seal can be provided simultaneously by using an interposer. This achieves a synergistic effect that can be provided in a particularly production-efficient manner—namely by attaching an interposer. The interposer has also proven to be useful for the measurement of sound events as such in the context of the invention, as it has been possible to shorten conductive paths, particularly with regard to electrical contacts, such that optimized signal transfer and simultaneous energy savings per area are achieved.

In a further preferred embodiment, the system according to the invention is characterized in that the MEMS microphone is in contact with a circuit carrier, preferably a printed circuit board, wherein the circuit carrier, preferably a printed circuit board, has a cavity for receiving the MEMS microphone. Preferably, the interposer makes electrical contact between the MEMS microphone and a circuit carrier, preferably a printed circuit board. The MEMS microphone is preferably placed on the circuit carrier (see FIG. 4B). Advantageously, the cavity offers optimum protection for the MEMS microphone, as the MEMS microphone fits perfectly into the cavity and the damping element above the cavity, in which the MEMS microphone is located, protects against the ingress of undesirable substances. The cavity can be located in the circuit carrier and is particularly easy to fit. The cavity within the circuit carrier is also advantageous for shortening conductive paths and transmitting electrical signals particularly well and efficiently. The MEMS microphone is also particularly stable, robust and fixed within the cavity, such that the MEMS microphone is not displaced in any way when the system according to the invention is subjected to stress, for example due to displacement and/or movement. This advantageously increases the overall component quality and the service life of the system according to the invention. The cavity can thus advantageously be seen as a protective space for the MEMS microphone, whereby electrical signals can be transmitted particularly easily and efficiently from and/or into the cavity in which the MEMS microphone is located.

The cavity refers to a hollow space that has a volume. The MEMS microphone can be located within this volume. The cavity has substantially the same dimensions as the MEMS microphone, but can have greater or smaller dimensions as desired.

Advantageously, an interposer offers the possibility of providing the damping membrane with simultaneous electrical contacting. In particular, in addition to the damping function, the interposer also allows the provision of intermediate circuits, vias and/or rewiring. In addition, the interposer provides an acoustic seal.

In the prior art, an interposer preferably refers to an intermediate layer or a component that mediates electrical connections between two or more terminals. The purpose of an interposer is usually to distribute a connection over a wider grid of connections or to redirect a connection to another connection. One example of an interposer relates to the provision of a so-called ball grid array, which is a housing form of integrated circuits in which the connections for SMD assembly are compactly located on the underside of the component. The connections are small solder balls, which are arranged next to each other in a grid form consisting of columns and rows. These balls are melted during a reflow process in a soldering oven and connect to contact pads on the PCB. A ball grid array as an interposer thus provides a connection between the terminals of a die with an integrated circuit (on the top side of the interposer) and the terminals or contact pads (on the bottom side of the interposer) of a printed circuit board.

In the context of the invention, the interposer is preferably a component that provides a connection between first terminals of the MEMS microphone and second terminals of a circuit carrier (preferably a printed circuit board). The component is preferably flat and can therefore be described as a layer. For the example of a ball grid array described above, the interposer is an intermediate layer that provides a connection between the connections on one side (top side) to an opposite side (bottom side).

In accordance with the invention, it may be preferred that the interposer also provides a connection between connections for the MEMS microphone and a circuit carrier (preferably a printed circuit board) from one side of the interposer to the other. Particularly preferably, however, the interposer provides a connection between connections for the MEMS microphone (in particular in a bottom-port design) and a circuit carrier (preferably a printed circuit board) on the same side of the interposer (see, inter alia, FIGS. 1-3).

In the context of the invention, the interposer can therefore preferably also be referred to as a cap or a cover layer. Particularly preferably, the interposer, as a cap or cover layer, closes off the MEMS microphone from one side (on which the sound inlet opening is present) and preferably provides a connection to the terminals of a printed circuit board on the side contacting the MEMS microphone.

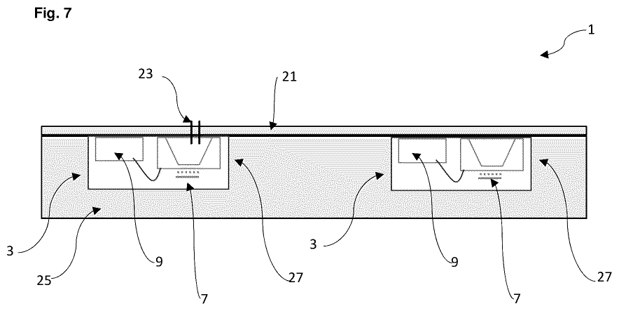

The interposer can preferably comprise both flexible and rigid materials. Rigid interposers are particularly preferred, as they can establish a particularly firm and robust connection with the MEMS microphone and protect the MEMS microphone in the sense of a cap or microphone cover (see, for example, FIGS. 6-7).

Silicon, glass and/or polyimide are particularly suitable materials for the interposer due to the processing options and low production costs. The interposer can be attached to the MEMS microphone using adhesive, soldering and/or bonding methods known in the prior art.

The damping membrane is preferably integrated in the interposer, such that the interposer simultaneously serves to establish a contact between the MEMS microphone and a circuit carrier and also provides advantageous elastic damping.

In a preferred embodiment, the damping membrane is formed by introducing a cavity in an interposer, which can preferably be applied as a cover layer or cap on the MEMS microphone. For example, the interposer can be present in the form of a planar cap or a layer substantially consisting of an elastic material, wherein a cavity is introduced in such a way that a damping membrane of a desired thickness remains in the interposer. For the elastic material of the interposer (and thus of the damping membrane), analogous to the above explanations, materials are in particular preferably selected from a group comprising monocrystalline silicon, polysilicon, silicon dioxide, silicon nitride, silicon carbide, silicon germanium, silicon nitride, nitride, germanium, carbon, gallium arsenide, gallium nitride, indium phosphide, glass and/or a metal.

The position and lateral extension of the cavity in the interposer can preferably be selected such that the damping membrane of the interposer is in front of or above the sound inlet opening of the MEMS microphone in the connected state.

In a preferred embodiment, the system according to the invention is characterized in that the damping membrane is formed by introducing a cavity in the interposer, wherein preferably a depth of the cavity is selected such that the damping membrane formed in the interposer has a thickness of 50 nm to 500 μm, preferably 100 nm to 200 μm, particularly preferably 1 μm to 50 μm and/or has a lateral extension of 100 μm to 2000 μm, preferably 200 μm to 1000 μm.

The values mentioned with regard to the thickness and lateral extension of the damping membrane resulting from the formation of a cavity in the interposer—in particular in combination with the materials mentioned—have proven to be very advantageous in that they can shift part of the sound pressure level without distortion, such that in particular high values of sound pressure levels can be measured by the microphone membrane.

By selecting the elastic material and thickness, values of approx. 10 dB, approx. 20 dB, approx. 30 dB, approx. 40 dB, approx. 50 dB or more can be advantageously shifted without distortion.

The cavity can be achieved using etching processes, which have established themselves as efficient, fast, reliable and cost-effective in the prior art.

The terms “etching methods” and “etching processes” can be used synonymously. An etching method preferably refers to the removal of material from a surface. The removal can take the form of depressions that leave cavities, wherein a boundary layer to the cavity leaves behind the damping element or the damping membrane.

Suitable etching methods for forming a damping membrane with the desired thickness would be, for example, wet chemical etching processes and/or dry etching processes, preferably physical and/or chemical dry etching processes, particularly preferably by reactive ion etching and/or reactive ion deep etching (Bosch process), or a combination of the aforementioned etching processes.

In semiconductor technology and microsystems technology, dry etching refers to a group of ablative microstructure processes that are not based on wet-chemical reactions (such as wet-chemical etching, chemical-mechanical polishing). The material is removed either by accelerated particles or with the aid of plasma-activated gases.

Dry etching processes can be divided into three groups: Physical dry etching processes, which are based on the removal of material by bombardment with particles, chemical dry etching processes, which are based on a chemical reaction of a mostly plasma-activated gas, and physicochemical dry etching processes, which use both mechanisms of action.

In wet chemical etching, an etch-resistant mask is transferred to the wafer by a chemical removal process.

Plasma etching is a material-removing, plasma-assisted dry etching process. In plasma etching, a distinction is made between etching removal due to a chemical reaction and physical removal of the surface due to ion bombardment.

In chemical plasma etching, the material is removed by a chemical reaction. It is therefore generally isotropic and, due to its chemical nature, also very material-selective. Physical plasma etching, also known as plasma-assisted ion etching, is a physical process. This process can result in a certain preferred direction in the etching attack, which is why the processes may exhibit anisotropy in the material removal.

In particular, reactive ion etching (RIE), an ion-assisted reactive process with very good controllability of the etching behavior, and deep reactive ion etching (DRIE), a further development of RIE, should be mentioned here.

The etching processes mentioned are known to the average person skilled in the art. Depending on the desired thickness of the damping membrane and/or the material of the interposer, advantageous processes can be selected to ensure efficient implementation.

In a preferred embodiment, the interposer has a thickness of up to 1000 μm, preferably up to 700 μm, particularly preferably between 400 and 700 μm.

Such layer thicknesses ensure that the interposer is particularly stable and robust and that a damping membrane with preferred thicknesses of 50 nm to 500 μm, preferably 100 nm to 200 μm, particularly preferably 1 μm to 50 μm can be introduced efficiently and safely. A circuit carrier is preferably a component comprising an electrically insulating material on which electrically conductive connections (conductor tracks) and/or electronic components or assemblies are present, preferably from semiconductor technology and microsystems technology.

In particular, a circuit carrier has metallic conductor tracks so that electrical connections can be made. They are preferably used for current or voltage supply, signal transmission and/or temperature dissipation.

In preferred embodiments, the circuit carrier is a printed circuit board, wherein both conventional (rigid) printed circuit boards and flexible printed circuits can be used.

Printed circuit boards comprise electrically insulating material with conductive connections, the conductor tracks, attached to it. The insulating material is usually fiber-reinforced plastic or, in the case of cheaper devices, laminated paper. The conductor tracks are usually etched from a thin layer of copper. The components are soldered onto soldering surfaces (pads) or into lands. In this way, they are held in a manner that is mechanically stable and electrically connected at the same time. Larger components can also be attached to the printed circuit board using cable ties, adhesive or screw connections.

The provision of an interposer with an integrated damping membrane and contact to a circuit carrier (preferably a printed circuit board) enables an extremely compact and robust system design. The circuit carrier can also be used to implement additional electrical and mechanical functions and can be designed in any shape.

One advantage is the ease of handling and automation when making contact with a printed circuit board via an interposer.

In a further preferred embodiment, the system according to the invention is characterized in that a closed electrical connection is formed between the MEMS microphone and the interposer, preferably in the form of a solder ring, around the sound inlet opening, which provides both an electrical contact between the MEMS microphone and the interposer and an acoustic seal. The electrical contact is preferably made by a solder ring around the sound inlet opening in the bottom port version of a MEMS microphone.

Advantageously, a particularly stable and robust electrical and mechanical connection is formed between the MEMS microphone and the interposer. In particular, the connection also acts as an acoustic seal for the MEMS microphone.

A solder ring preferably refers to a material (preferably soldering material) that is substantially ring-shaped, i.e. in particular closed, structured on the interposer and is used to attach the MEMS microphone to the interposer, preferably via soldering processes. Other processes such as bonding and/or gluing can also be used.

An acoustic seal preferably refers to a terminating resistor in relation to electrical signals generated by the sound waves. Terminating resistors are resistors at conductor ends that correspond to the impedance of the conductor or electrical connection and terminate it with the correct impedance. Due to the impedance-correct seal, the waves transmitted on the transmission medium run out at infinity and cannot be reflected (not even partially).

In a further preferred embodiment, the system according to the invention is characterized in that a space between the MEMS microphone, an interposer and/or a circuit carrier, preferably a printed circuit board, is filled with a filling material.

Advantageously, filling the space with a filling material results in a particularly high level of stabilization and a rear seal. In particular, in respect of the stabilization, the filling material largely prevents the interposer and/or the circuit carrier, which is coupled to the damping membrane, from resonating. In particular, for the purpose of shifting to a measurable level, only the damping membrane is preferably made to vibrate i.e. in particular the area above the sound inlet opening, but not lateral areas of the interposer and/or the intermediate circuit. Advantageously, only the damping membrane is subjected to mechanical stress and not the entire interposer and/or circuit carrier. This results in particularly accurate measurement results. In particular, high values of the sound pressure level are shifted undistorted to a range that can be measured by the microphone membrane.

A space here preferably refers to one or more gaps between the MEMS microphone, the interposer and/or the circuit carrier. Without the filling, the space would only contain air or a vacuum. The space occurs when one or more components in contact with each other have a shape other than a rectangular profile. The space can be a planned predetermined breaking point or separation point of the components, which are mounted immovably to each other or are fixed to each other.

In a further preferred embodiment, the system according to the invention is characterized in that the filling material comprises one or more polymers, preferably one or more cyclic, linear, branched and/or crosslinked polysiloxanes.

In this respect, the materials mentioned are very advantageous as a filling material, as they exhibit good resistance behavior. The filling material remains stable in a wide temperature range (e.g. from approx. −40° C. to approx. +150° C.) in terms of its mechanical behavior on the one hand, but also in terms of its appearance, i.e. no yellowing occurs over time compared to other plastics. Another advantage is that the aforementioned materials have a certain elasticity. This can be relevant, for example, when high mechanical stresses occur, for example due to the effect of very high pressures, as is common in aeroacoustics. As a result, the functionality of the system according to the invention remains intact despite the effect of high forces, for example. Due to the relatively weak intermolecular bonds of the aforementioned materials, they also have a low viscosity, which can be advantageous during production and processing. The relatively low viscosity is also associated with production-related advantages. The processes are easier to handle, short cycle times can be achieved and production can be carried out to very tight tolerances. In addition, very complex geometries can be molded due to the flow behavior of the material.

In a further preferred embodiment, the system according to the invention is characterized in that the damping membrane is integrated in or formed by a microphone cover, wherein the microphone cover optionally comprises an opening for pressure equalization. Preferably, the microphone cover can be used as a damping membrane in the case of a top port version of a MEMS microphone (see e.g. FIG. 5-6). In particular, the damping membrane can be provided by the housing or by an additionally attached cover. The microphone cover may, for example, comprise one or more foils or a membrane formed from metal, glass and/or one or more polymers. The microphone cover may also be in the form of a cap. It may also be preferred that the microphone cover is attached to a bottom port version of a MEMS microphone (see FIG. 7). In the bottom-port version, the microphone cover is preferably attached in such a way that it extends laterally along the sound inlet opening and is located on the carrier substrate.

Advantageously, attaching the damping membrane to a microphone cover is particularly easy, especially using etching processes to form the damping membrane. At the same time, the microphone membrane provides excellent protection for the MEMS microphone. The microphone cover can be located over an area of the sound inlet opening, over a further area or along an entire surface above the sound inlet opening. Furthermore, it is advantageous that it is particularly easy to make openings in the microphone membrane, which preferably serve to enable pressure equalization between the surroundings of the system according to the invention and the system according to the invention itself. In particular, the microphone cover may comprise a vibratable material, for example a vibratable polymer, such that large sound variables measured at the microphone membrane, such as high sound pressure levels, are shifted undistorted to measurable ranges, for example by at least about 10 dB, about 20 dB, about 30 dB or more. In particular, there is no loss of bandwidth of the measured signal and the signal-to-noise ratio remains the same.

Pressure equalization is preferably defined as a process in which substantially the same pressure is established between the system according to the invention and its surroundings, which are preferably filled with the same medium. The medium can be either a gas or a liquid, in particular also air. Preferably, the pressure equalization is achieved by transporting the medium between the surroundings and the system according to the invention. Advantageously, pressure equalization enables substantially the same vibration behavior of the damping membrane and the microphone membrane. If there were no pressure equalization, this could have a detrimental effect on the sensitivity and on the overall functional operation. It is therefore preferable for pressure equalization to take place through openings in the microphone cover.

The microphone cover preferably refers to a component of the system according to the invention that exhibits a large planar extension in relation to its thickness. In particular, the microphone membrane is a biaxially stretched surface that has the ability to separate and/or vibrate. For example, the microphone cover may comprise foils or a membrane formed of metal, glass, and/or one or more polymers. The microphone cover may also be attached in the form of a cap, the housing or part of the housing.

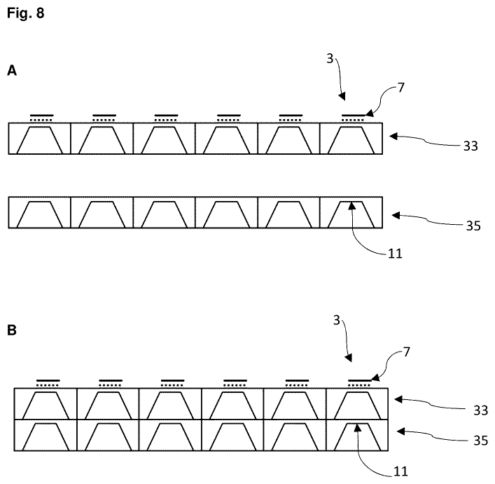

In a further preferred embodiment, the system according to the invention is characterized in that the system comprises at least two wafers forming a wafer stack, wherein the MEMS microphone is present in a first wafer and the damping membrane is present in a second wafer. Preferably, the damping membrane can be present through a cavity within a wafer. Preferably, the wafers are joined together in such a way that the damping membrane is located in front of the sound inlet opening (see FIG. 8A-B).

The formation of a multi-layer substrate, preferably a wafer stack, is formed from at least two wafers, but can also comprise 3, 4, 5, 6, 7, 10, 15, 20 or more wafers. The wafers can be joined together both horizontally and vertically in two or more layers to form a three-dimensional configuration. Vertical electrical connections between different wafers are made possible by vias. Other layers, such as one or more oxide layers, can also be located between the wafers of a wafer stack.

Advantageously, this results in a smaller footprint. More functional components fit on a smaller area of the component carrier, e.g. on the circuit board. This enables smaller and at the same time powerful MEMS microphones. The design is also advantageously associated with lower production costs. It is also advantageous that the production of the individual components can be optimized to a much higher degree than if they are produced together on a single substrate. In particular, this means that components from different and incompatible manufacturing techniques can be combined in one wafer stack. This also results in shorter signal paths and lower power consumption. The use of an additional dimension enables a higher order in the connectivity of the components and thus new possibilities in the structure and design.

The terms “wafer” and “substrate” can be used synonymously. The wafer may comprise materials selected from the group consisting of monocrystalline silicon, polysilicon, silicon dioxide, silicon carbide, silicon germanium, silicon nitride, nitride, germanium, carbon, gallium arsenide, gallium nitride, indium phosphide and/or glass.

These materials are particularly easy and inexpensive to process in semiconductor and/or microsystems technology and are also well suited for mass production. These materials are also particularly suitable for doping and/or coating in order to achieve the desired electrical, thermal and/or optical properties in certain areas. The aforementioned materials offer a variety of advantages due to the usability of standardized production techniques, which are also particularly suitable for the integration of additional components.

Processing for producing the system according to the invention is particularly simple. In particular, bonding processes established in the prior art can be used to join the wafers together.

It may also be preferable for individual wafers to be thinned using known polishing processes from microsystems technology, for example. The wafers can be thinned before or after bonding. Vertical electrical connections (vias) can also be made either before bonding or after the stack has been produced.

The bonding of wafers preferably describes a process step in semiconductor and microsystem technology in which two wafers or slices, e.g. made of silicon, quartz, glass and/or the aforementioned preferred materials, are bonded together.

Various processes can preferably be used for bonding. These are also referred to as bonding processes or bonding methods. Preferred bonding processes include direct bonding, anodic bonding, interlayer bonding, glass frit bonding, adhesive bonding and/or selective bonding.

In direct bonding, particularly of silicon wafers, hydrophilic and hydrophobic surfaces of the wafers are preferably brought into contact at high temperatures. Preferably, one wafer is pressed centrally against the other, advantageously creating a first contact point. This mechanical connection in the contact area is preferably based on hydrogen bonds and/or van der Waals interactions. The contact area thus connected is preferably extended to the remaining wafer surface(s) by successively removing initially existing spacers between these surfaces. The process temperatures are preferably between 1000° C. and 1200° C. and a pressure of between 10 megapascals (MPa) and 25 MPa is exerted on the wafers. Direct bonding can preferably be used for joining two silicon wafers and/or silicon dioxide wafers.

In anodic bonding, a glass with an increased Na+ion concentration (preferably positively charged sodium ions) is used in particular, which is preferably brought into contact with a silicon wafer. An electrical voltage is applied, which is configured in particular to generate a negative polarity on the glass. Thus, preferably and in particular with the aid of an increased process temperature, the sodium ions (Na+) diffuse to the electrode, preferably forming a space charge zone at the interface, which causes an increase in the electric field and generates Si—O—Si bonds. These bonds preferably expand successively over the entire bonding surface between glass and silicon. In this way, glass and silicon wafers in particular can be bonded together. If the process is adapted accordingly, it is also possible to bond two silicon layers and/or a silicon-metal layer to a glass. The anodic bonding can preferably take place at temperatures of around 400° C., it can also preferably take place at “low temperature” at around 180° C., whereby the materials to be bonded are preferably protected. Preferably, various of the aforementioned materials can also be bonded.

Preferably, bonding processes with so-called intermediate layers between the wafers to be bonded can also be used, such as eutectic bonding, which is preferably based on bonding using a eutectic alloy as an intermediate layer, e.g. Si—Au (silicon-gold) or Ge—Al (germanium-aluminum). A eutectic alloy is preferably an alloy whose components are mixed in such a ratio that the entire alloy becomes liquid or solid at a certain temperature. Eutectic bonding can be used, for example, to join two silicon wafers. Preferably, however, other aforementioned materials can also be bonded.

Glass frit bonding is also preferably based on the use of an intermediate layer between the wafers to be bonded, whereby the bond is formed in particular by melting glass solders/glass frits. Glass solder preferably comprises a glass which has a low softening temperature, e.g. approx.

400° C. Glass frits preferably comprise surface-melted glass powder, the glass grains of which preferably at least partially bake or sinter together. This type of bonding can preferably combine silicon and/or silicon dioxide wafers, but preferably also other aforementioned materials.

Adhesive bonding preferably describes the formation of a bond by means of an intermediate layer comprising adhesive. Adhesive bonding can preferably be used to bond various of the aforementioned materials together.

Preferably, selective bonding can be carried out by photolithography, etching and/or lift-off processes.

The bonding of structures from pre-processed wafers allows the simple production of complex structures that could be produced from a single wafer only at great expense. This means that the semiconductor component can be produced without the raw material having to be laboriously machined out of the interior in order to provide the damping membrane on a wafer.

In a further aspect, the invention relates to the use of the system according to the invention for aeroacoustic measurements, preferably for measuring sound pressure waves on surfaces of a vehicle component.

Particularly in the case of measurements for or in aircraft, aircraft components, vehicles such as automotive systems and/or automotive components, the sound variables can assume very high values, in particular with regard to the sound pressure level. Advantageously, the system according to the invention enables the measurement of such high values, in particular for measurements relating to high sound pressure levels.

The sound pressure level in particular is shifted to a measurable range by the damping element or damping membrane. This is achieved by causing the damping membrane to vibrate in the same way as the microphone membrane. In particular, the shift to a measurable range is substantially undistorted and without loss of the signal-to-noise ratio. The damping membrane and the microphone membrane exhibit substantially the same vibration behavior, although they preferably differ in their amplitude and phase. The phase shift occurs because the damping membrane vibrate first before the microphone membrane vibrates. For example, the damping membrane can shift the sound pressure level by at least approx. 10 dB, approx. 20 dB, approx. 30 dB or more via the vibrations, such that the system according to the invention can be used at very high sound pressure levels, e.g. at approx. 180 dB. Such high sound pressure levels are achieved in particular when there is a high relative velocity with respect to a flowing fluid, for example high flow and/or wind velocities.

Due to the small dimensions of the system according to the invention, the flow of the fluid is advantageously not and only very slightly influenced, such that small lateral resolutions of large sound variables such as the sound pressure level are advantageously made possible.

In addition, the system according to the invention has a substantially planar design, such that it can be integrated very easily and efficiently on surfaces. It is conceivable, for example, that the system according to the invention could be installed on aircraft components such as the elevator, ailerons, etc.

The system according to the invention is very simple, efficient and has proven to be very advantageous in terms of handling, production finishing and further processing.

The system according to the invention will be explained in more detail below using examples, without being limited to these examples

### FIGURES

### Brief Description of the Figures

FIG. 1 Illustration of a preferred embodiment of the system according to the invention by mounting the damping membrane in an interposer

FIG. 2 Illustration of a preferred embodiment of the system according to the invention by mounting on a circuit carrier

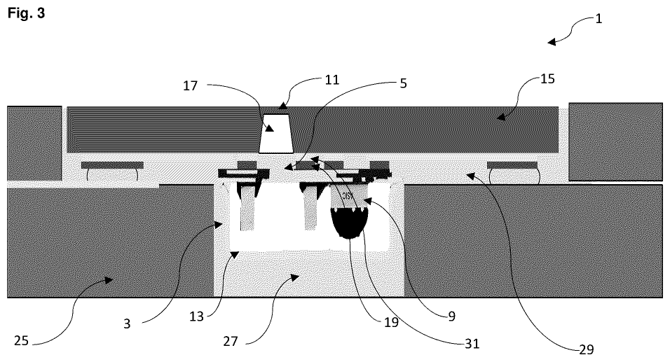

FIG. 3 Illustration of a preferred embodiment of the system according to the invention by mounting on a circuit carrier and filling the intermediate space with a filling material

FIG. 4 Illustration of a preferred embodiment of the system according to the invention by attaching the damping membrane to a cavity of a circuit carrier

FIG. 5 Illustration of a preferred embodiment of the system according to the invention by mounting the damping membrane in a microphone cover

FIG. 6 Illustration of a further preferred embodiment of the system according to the invention by mounting the damping membrane in a microphone cover in a top port configuration

FIG. 7 Illustration of a further preferred embodiment of the system according to the invention by mounting the damping membrane in a microphone cover in a bottom port configuration

FIG. 8 Illustration of a further preferred embodiment of the system according to the invention in a wafer stack

FIG. 9 Illustration of a modeling of the damping by the system according to the invention

### DETAILED DESCRIPTION OF THE FIGURES

FIG. 1 is an illustration of a preferred system 1, in which a damping membrane 11 is inserted into an interposer 15. The damping membrane 11 is attached by forming a cavity 17 in the interposer 15. The cavity 17 can be formed using etching processes established and known in the prior art, which have been listed and described above. The damping membrane 11 on the interposer 15 is placed in front of a sound inlet opening 5 of a MEMS microphone 3. For aeroacoustic applications or measurements, the sound inlet opening 5 is located in the direction of air flow. For mechanical and/or electrical contacting, a solder ring 19 and a metal pad 31 are located on the interposer 15 and/or on the MEMS microphone 3. The MEMS microphone 3 exhibits an electronic circuit 9, which can be in the form of an ASIC, for example (identified by the term ASIC), a housing 13 and a vibratable microphone membrane 7. Sound can pass through the sound inlet opening 5 and reach the microphone membrane 7. Upon incidence of the sound waves, the microphone membrane 7 is excited and set into vibration.

An electrical signal dependent on the sound waves is generated by the electronic circuit 5, wherein sound variables of the sound waves can be measured and/or determined. With the MEMS microphones known in the prior art, it is not possible to measure high sound pressure levels, for example at around 175 dB. The microphone membrane of the already known MEMS microphones is not designed for such high sound pressure levels. In order to be able to measure such high sound pressure levels, the damping membrane 11 is attached, which is also set into vibration when sound waves are incident upon it.

The damping membrane 11 or the interposer 15 comprises a material that is elastically deformable but not plastically deformable, e.g. silicon, silicon oxide, silicon nitride, glass, ceramic or other organic material, whereby the blue color in FIG. 1 is intended to represent silicon. This allows the damping membrane 11 and the microphone membrane 7 to have substantially the same vibration behavior. This is of great advantage, as the sound pressure level is shifted undistorted to a range that can be measured by the microphone membrane 7 due to vibrations of the damping membrane 11.

In particular, the signal-to-noise ratio of the measured signal is maintained. Sound pressure levels can be reduced by at least 10 dB, at least 20 dB or at least 30 dB. This is achieved by dividing the sound energy of the sound waves between the vibrations of the damping membrane 11 and the microphone membrane 7. Another major advantage of the system 1 according to the invention is that it has small dimensions. As a result, the flow behavior of the air flowing around it is essentially not or only slightly influenced, such that accurate and authentic measurement results can be obtained. Furthermore, the system 1 according to the invention has a planar design such that it can be integrated particularly easily and efficiently on surfaces. In addition, the system 1 according to the invention forms a closed system such that dirt particles can be removed particularly easily and, in particular, cannot enter. This advantageously increases the overall component quality.

FIG. 2A-B shows an illustration of a further preferred embodiment of the system 1 according to the invention. Here, the system 1 according to the invention is mounted on a circuit carrier 25. FIG. 2A shows the system 1 according to the invention before it is attached to the circuit carrier 25. FIG. 2B shows the system 1 according to the invention, which is now mounted on the circuit carrier 25. The circuit carrier can be a printed circuit board, for example.

The system 1 according to the invention is placed on the circuit carrier 25 in such a way that the MEMS microphone 3 is located within a cavity 27 of the circuit carrier, whereby a space 29 can form between the MEMS microphone 3, the interposer 15 and/or the circuit carrier 25. The cavity 27 provides optimum protection for the MEMS microphone. Within the cavity, the MEMS microphone 3 is particularly stable, robust and fixed such that no damage to the internal components of the MEMS microphone 3 occurs in the event of stresses, for example due to displacements caused by high air flow velocities. Furthermore, a very compact design can be achieved in this way, which makes it easier to integrate the MEMS microphones into a surface. In addition, conductor paths are shortened and efficient transmission of electrical signals is ensured.

FIG. 3 shows a representation of a preferred embodiment with filling of the intermediate space 29 with a filling material. The filling material may comprise one or more polymers, preferably one or more cyclic, linear, branched and/or cross-linked polysiloxanes. By filling the intermediate space with a filling material, a particularly high degree of stabilization and a rear closure of the system 1 according to the invention is achieved. In addition, the filling material preferably prevents the interposer and/or the circuit carrier from resonating as far as possible. To shift the sound pressure level to a measurable range, preferably only the damping membrane is set into vibration, i.e. in particular the area above the sound inlet opening.

FIG. 4A-B shows an illustration of a preferred embodiment of the system according to the invention by attaching the damping membrane 11 to the cavity 27 of the circuit carrier 25. In FIG. 4A, the damping membrane 11 is first attached over the sound inlet opening 5 of the MEMS microphone 3. It can be attached using bonding, adhesive and/or soldering processes. In FIG. 4B, this is placed in the circuit carrier 25 in such a way that the damping membrane is located inside the cavity 27. This embodiment is particularly relevant in SMD (surface-mounted device) technology. While the connecting wires of conventional components are fed through mounting holes and have to be soldered on the back of the PCB (or via inner layers), this is not necessary in SMD technology or in SMD components. This enables very dense assemblies and, above all, assembly on both sides of the PCB. The electrical properties of the circuits are positively influenced, in particular at higher frequencies. Furthermore, the spatial requirement of the components is reduced.

FIG. 5 shows an illustration of a preferred embodiment of the system 1 according to the invention by attaching the damping membrane 11 to a microphone cover 21. In this case, the microphone cover 21 itself can act as a damping membrane. This means that the microphone cover 21 itself is set into vibration when sound waves occur and the sound pressure level can thus be shifted, for example by approx. 20 dB. It is also possible that only an area above the sound inlet opening 5 is set into vibration, the damping membrane 11, such that the sound pressure level is shifted undistorted to a range that can be measured by the microphone membrane 7. Openings 23 may be present on the microphone cover 21 which equalize the pressure between the system 1 according to the invention and its surroundings. In particular, two systems 1 according to the invention are on one circuit carrier 25. The system 1 according to the invention can thus also be designed as an array to enable high-resolution sound measurement in aeroacoustics, for example.

FIG. 6 shows an illustration of a further preferred embodiment of the system according to the invention by attaching a microphone cover 21 over a MEMS microphone in a top-port version. In this case, the sound is incident on the microphone membrane 7 via the top of the housing. In particular, the rear volume of top-port versions of a MEMS microphone 3 has a smaller air volume than the front volume. The microphone cover 21 can be in the form of a cover and/or a film formed from an elastic material. Preferably, only one area of the microphone cover 21 can vibrate above the sound inlet opening 5, or other lateral areas or the entire surface can vibrate in order to attenuate the sound pressure level from measurable areas of the microphone membrane 7.

FIG. 7 shows a similar illustration to FIG. 6, but FIG. 7 shows a bottom-port version of the MEMS microphone 3. In bottom-port microphones, the microphone membrane is usually positioned directly above the sound inlet opening 5, which offers a number of advantages. In particular, the rear volume of bottom-port versions of a MEMS microphone 3 has a larger rear volume than the front volume. A large volume of air in the rear volume makes it easier for the microphone membrane 7 to move under the influence of the sound waves. This in turn improves the sensitivity and the signal-to-noise ratio of the MEMS microphone 3. The response of the MEMS microphone 3 to low frequencies also benefits from a rear volume.

FIG. 8 shows a representation of a further preferred embodiment of the system according to the invention within a wafer stack. The MEMS microphone 3 comprising the microphone membrane 7 in a first wafer 33 and the damping membrane 11 in a second wafer 35. Here, the damping membrane 11 is provided by forming a cavity in the second wafer 35. FIG. 8A shows the two wafers 33 and 35 before bonding and FIG. 8B shows the two wafers 33 and 35 after they are bonded together to form a wafer stack. In particular, this illustration shows that an array of MEMS microphones 3 can be formed along the first wafer 33 and an array of damping membranes 11 can be formed along the second wafer 35. Here, the processing for producing the wafer stack is particularly simple. In particular, established prior art bonding processes can be used to bond the wafers 33 and 35 together.

FIG. 9A-D shows a preferred embodiment of the system 1 according to the invention with modeling in the context of an equivalent circuit diagram and simulation results with regard to some parameters of the damping membrane 11.

FIG. 9A shows a preferred embodiment of the system 1 according to the invention. The cavity 17 is attached to the interposer 15 such that the damping membrane 11 is formed on the interposer 15. The damping membrane can shift high sound pressure levels to ranges measurable by the microphone membrane 7 while maintaining the bandwidth, for example by a shift of at least approx. 10 dB, at least approx. 20 dB or at least approx. 30 dB or more. This is achieved by dividing the sound energy between the vibrations of the microphone membrane 7 and the damping membrane 11. A height h indicates the height or thickness of the damping membrane 11 and a parameter R its radius.

FIG. 9B shows the same embodiment in FIG. 9A, but with an additional equivalent circuit diagram, which is used for modeling the system 1 according to the invention. A voltage source for supplying electrical energy is shown at the top of the circuit diagram, which in the context of the invention corresponds to a sound wave for supplying sound energy. The voltage source supplies current, which is fed to a capacitor 37, e.g. a plate capacitor. The capacitor 37 corresponds to the damping membrane 11 of the system according to the invention. When sound waves are incident on the damping membrane 11, it is deflected and set into vibration, wherein the damping membrane absorbs sound energy, analogous to the storage of electrical energy in a plate capacitor 37. The cavity 17 and the front volume can be modulated by one or more coils connected in series. The air volume in the rear volume is also a factor to be taken into account, which can also be modeled by a coil 39, whereby the microphone membrane 7 and a rear wall can also be modulated by capacitors 37 in the circuit diagram.

As a modeling of the acoustic system using the electronic circuit diagram shows, the vibration behavior and thus the ability to reduce the sound pressure levels depends on a number of parameters. This becomes clear in FIGS. 9C and 9D.

For FIG. 9C, the thickness of the damping membrane or the panel thickness h was varied for the simulation, but the radius R was kept constant. The y-axis shows the sound pressure level in negative dB and the x-axis shows the frequency in a logarithmic representation. The simulation results show that a uniform, distortion-free reduction of the sound pressure level is possible over a wide frequency range.

Furthermore, the results show that a desired reduction in the sound pressure level can be specifically set by selecting the panel thickness. In particular, the greater the panel thickness h (the thickness of the damping membrane), the greater the reduction in the sound pressure level. Compared to the case without a damping membrane, a damping membrane with a plate thickness h of approx. 6.25 μm, for example, can reduce the sound pressure level from approx. −40 dB (without plate) to approx. −60 dB. A panel thickness of approx. 200 μm achieves a reduction to a sound pressure level of approx. −150 dB over a wide frequency range.

In FIG. 9d, the same simulation is carried out, but now the plate thickness h is kept constant at 400 μm, while the radius R of the plate or damping membrane 11 is varied, which corresponds to the lateral extension of the damping membrane 11. A desired reduction in the sound pressure level can also be set by selecting the radius of the damping membrane. In particular, the smaller the radius of the damping membrane, the higher the reduction in sound pressure level.

With a radius of approx. 500 μm—which almost corresponds to the sound inlet opening—the signal is approx. −165 dB over a wide frequency range of 100 Hz-10 KHz, while a radius of approx. 300 μm reduces this to approx. —200 dB.

### REFERENCE LIST

1 System
3 MEMS microphone
5 Sound inlet opening
7 Microphone membrane
9 Electronic circuit (e.g. ASIC)
11 Damping membrane
13 Housing
15 Interposer
17 Cavity in the interposer
19 Solder ring
21 Microphone cover
23 Opening in the microphone cover
25 Circuit carrier
27 Cavity in the circuit carrier
29 Space
31 Metal pad
33 First wafer
35 Second wafer
37 Capacitor
39 Coil
H Height of the damping membrane or panel thickness
R Radius of the damping membrane

### BIBLIOGRAPHY

Martin, David T., et al. “A micromachined dual-backplate capacitive microphone for aeroacoustic measurements.” Journal of Microelectromechanical Systems 16.6 (2007): 1289-1302.
Sheplak, Mark, et al. “A MEMS microphone for aeroacoustics measurements.” 37th Aerospace Sciences Meeting and Exhibit. 1999.
Horowitz, Stephen, et al. “Development of a micromachined piezoelectric microphone for aeroacoustics applications.” The Journal of the Acoustical Society of America 122.6 (2007): 3428-3436.

1. A system comprising
(a) a MEMS microphone comprising a sound inlet opening, a vibratable microphone membrane and an electronic circuit, wherein when the microphone membrane is induced into vibrations by sound waves entering through the sound inlet opening, an electrical signal that is dependent on the sound waves is generated, and
(b) a damping element for reducing a sound pressure level of the sound waves acting on the microphone membrane
wherein the damping element comprises an elastic and vibratable damping membrane, which is mounted in front of the sound inlet opening and, in addition to the microphone membrane, is induced into vibrations by the sound waves, such that sound energy of the sound waves is divided between the damping membrane and the microphone membrane,
wherein dividing the sound energy of the incident sound waves between the damping membrane and the microphone membrane leads to a reduction in the sound pressure level acting on the microphone membrane by at least 10 dB and wherein the system comprises an interposer and the damping membrane is located in the interposer.

2. The system according to claim 1, wherein dividing the sound energy of the incident sound waves between the damping membrane and the microphone membrane leads to a reduction in the sound pressure level acting on the microphone membrane by at least 10 dB.

3. The system according to claim 1, wherein the damping membrane is formed from an elastic material.

4. The system according to claim 1, wherein the damping membrane exhibits a thickness of 50 nm to 500 μm, and/or the damping membrane extends at least over the sound inlet opening and/or the damping membrane exhibits a lateral extension of 100 μm to 2000 μm.

5. The system according to claim 1, wherein the MEMS microphone is present in a top-port or bottom-port design and/or is integrated within a multilayer substrate, and/or the MEMS microphone is a capacitive, piezoelectric and/or piezoresistive MEMS microphone and/or an electret microphone.

6. (canceled)

7. The system according to claim 1 wherein the damping membrane is formed by introducing a cavity in the interposer, wherein a depth of the cavity is selected such that the damping membrane formed in the interposer has a thickness of 50 nm to 500 μm, and/or has a lateral extension of 100 μm to 2000 μm.

8. The system according to claim 1, wherein the interposer has a thickness of up to 1000 μm, and/or the interposer provides an electrical contact between the MEMS microphone and a circuit carrier.

9. The system according to claim 1, wherein a closed electrical connection is formed between the MEMS microphone and the interposer, around the sound inlet opening, which provides both an electrical contact between the MEMS microphone and the interposer and an acoustic seal.

10. The system according to claim 1, wherein the damping membrane is integrated in or formed by a microphone cover, the microphone cover optionally comprising an opening for pressure equalization.

11. The system according to claim 1, wherein the system comprises at least two wafers forming a wafer stack, wherein the MEMS microphone is present in a first wafer and the damping membrane is formed in a second wafer.

12. The system according to claim 1, wherein the MEMS microphone is in contact with a circuit carrier, wherein the circuit carrier, exhibits a cavity for receiving the MEMS microphone.

13. The system according to claim 1, wherein a space between the MEMS microphone, an interposer and/or a circuit carrier is filled with a filling material.

14. The system according to claim 13, wherein the filling material comprises one or more polymers.

15. A method of making aeroacoustic measurements comprising using the system according to claim 1.

16. The system of claim 3, wherein the elastic material is selected from the group consisting of monocrystalline silicon, polysilicon, silicon dioxide, silicon nitride, silicon carbide, silicon germanium, silicon nitride, nitride, germanium, carbon, gallium arsenide, gallium nitride, indium phosphide, glass and a metal.

17. The system of claim 5, wherein the multilayer substrate is a wafer stack.

18. The system of claim 9, wherein the closed electrical connection formed between the MEMS microphone and the interposer is in the form of a solder ring.

19. The system of claim 14, wherein the one or more polymers are selected from the group consisting of cyclic, linear, branched and cross-linked polysiloxanes.

20. The method of claim 15, wherein sound pressure waves on surfaces of a vehicle component are measured.
